(19) United States
(12) Patent Application Publication
(10) Pub. No.: US 2025/0294931 A1
(43) Pub. Date: Sep. 18, 2025

(54) LIGHT EMITTING APPARATUS, VEHICULAR LAMP AND VEHICLE INCLUDING THE SAME

(71) Applicant: Seoul Semiconductor Co., Ltd., Gyeonggi-do (KR)

(72) Inventor: Jiho KIM, Ansan-si (JP)

(73) Assignee: Seoul Semiconductor Co., Ltd., Gyeonggi-do (KR)

(21) Appl. No.: 19/077,879

(22) Filed: Mar. 12, 2025

Related U.S. Application Data
(60) Provisional application No. 63/565,234, filed on Mar. 14, 2024.

(51) Int. Cl. H10H 20/853; B60Q 1/24; H10H 20/851

(52) U.S. Cl. CPC H10H 20/853; B60Q 1/24; H10H 20/8514

(57) ABSTRACT

Disclosed is a light emitting apparatus. The light emitting apparatus includes a substrate, a light emitting layer, a wavelength conversion layer, and a barrier layer. The light emitting layer may be disposed on the substrate and may include a light exit surface through which light is emitted. The wavelength conversion layer may be disposed on the light emitting layer. The barrier layer may be formed on the substrate to cover side surfaces of the light emitting layer and the wavelength conversion layer, and may reflect the light emitted from the light emitting layer. The light exit surface of the light emitting layer may include a first light exit region and a second light exit region having lower luminance than the first light exit region. The barrier layer may have a greater thickness in a region thereof surrounding the second light exit region than in a region thereof surrounding the first light exit region. Further, the thickness of the barrier layer may correspond to a distance from an inner side surface of the barrier layer to an outer side surface thereof.

### CROSS-REFERENCE TO RELATED APPLICATIONS

The present application is a non-provisional Application which claims priority to the benefit of U.S. Provisional Application No. 63/565,234 filed Mar. 14, 2024, the disclosure of which is incorporated by reference in its entirety.

### BACKGROUND

### Field

The present invention relates to a light emitting apparatus, a vehicular lamp including the light emitting apparatus, and a vehicle including the vehicular lamp.

### Discussion of the Background

A light emitting diode is a semiconductor device that emits light through recombination of electrons and holes, and has recently been used in many fields, such as displays, vehicular lamps, general lighting, and the like. With advantages of long lifespan, low power consumption, and fast response, light emitting diodes are applied to various fields, such as vehicular lamps, displays, and the like. For example, light emitting diodes are also applied to head-mounted displays (HMDs) and are widely applied to vehicular headlamps due to their excellent straightness of light.

However, a light emitting diode may fail to realize uniform luminance on a light exit surface for a variety of reasons.

Moreover, precise control of light radiation requires that each light emitting diode or a light emitting apparatus, such as a chip or package, including light emitting diodes, have a narrow beam angle.

### SUMMARY

Embodiments of the present invention provide a light emitting apparatus capable of improving luminance uniformity.

Embodiments of the present invention provide a light emitting apparatus that has a narrow beam angle while improving luminance uniformity.

In accordance with an aspect of the present invention, there is provided a light emitting layer including a substrate, a light emitting layer, a wavelength conversion layer, and a barrier layer. The light emitting layer may be disposed on the substrate and may include a light exit surface configured to emit light. The wavelength conversion layer may be disposed on the light emitting layer. The barrier layer may be disposed on the substrate, and may cover at least a side surface of the light emitting layer and at least a side surface of the wavelength conversion layer, and may reflect the light emitted from the light emitting layer. The light exit surface of the light emitting layer may include a first light exit region and a second light exit region having a lower luminance than the first light exit region. The barrier layer may include a first region adjacent to the first light exit region and a second region adjacent to the second light exit region, which is a greater thickness than the first region. Further, a thickness of the barrier layer may correspond to a distance from an inner side surface of the barrier layer to an outer side surface thereof.

An upper surface of the barrier layer may be substantially flat.

An upper surface of the barrier layer may include a first upper surface adjacent the first light exit region and a second upper surface adjacent the second light exit region. Each of the first upper surface and the second upper surface may include a first end coupled with the wavelength conversion layer and a second end placed opposite the first end. The first end and the second end of each of the first upper surface and the second upper surface may be placed higher than an upper surface of the light emitting layer.

The upper surface of the barrier layer may have a height gradually decreasing from an inner side edge of the barrier layer to an outer side edge thereof.

The second end of the first upper surface may be disposed higher than the second end of the second upper surface.

The upper surface of the barrier layer may include a curved surface.

The upper surface of the barrier layer may include a curved surface concave in a downward direction.

The second upper surface may have a greater radius of curvature than a radius of curvature of the first upper surface.

The wavelength conversion layer may cover an upper surface of the light emitting layer and may have a larger cross-sectional area than a cross-sectional area of the light emitting layer.

The wavelength conversion layer may have a larger cross-sectional area in a region thereof covering the second light exit region of the light emitting layer and an outer side surface of the second light exit region than in a region thereof covering the first light exit region of the light emitting layer and an outer side surface of the first light exit region.

A width from the outer side surface of the second light exit region to a second end of the wavelength conversion layer adjacent to the second exit region may be greater than a width from the outer side surface of the first light exit region to a first end of the wavelength conversion layer adjacent to the first light exit region.

In accordance with another aspect of the present invention, there is provided a light emitting apparatus including a substrate, a light emitting layer, a wavelength conversion layer, a barrier layer, and a blocking layer. The light emitting layer is disposed on the substrate and may include a light exit surface configured to emit light. The wavelength conversion layer may be disposed on the light emitting layer. The barrier layer may be disposed on the substrate configured to cover side surfaces of the light emitting layer and the wavelength conversion layer, and may reflect the light emitted from the light emitting layer. The blocking layer may cover at least a surface of the barrier layer. The light exit surface of the light emitting layer may include a first light exit region and a second light exit region having lower luminance than a luminance of the first light exit region. Further, the blocking layer may have a greater thickness in a region thereof adjacent to the first light exit region than a thickness in a region thereof adjust to the second light exit region.

The light emitting apparatus may further include a blocking layer surrounding a side surface of the barrier layer. The blocking layer may be configured to absorb the light emitted from the light emitting layer.

The blocking layer may have lower light transmittance than a light transmittance of the barrier layer.

An upper surface of the blocking layer may be placed lower than an upper surface of the wavelength conversion layer and higher than an upper surface of the light emitting layer.

An upper surface of the blocking layer may be placed higher than an upper surface of the wavelength conversion layer.

In accordance with a further aspect of the present invention, there is provided a vehicle including: a main body; a lamp mounted on a surface of the main body; and a plurality of light emitting apparatuses arranged on the lamp. At least one light emitting apparatus of the plurality of light emitting apparatuses may include at least one light emitting layer, a wavelength conversion layer covering an upper surface of the at least one light emitting layer, and a barrier layer covering a side surface of the at least one light emitting layer to reflect light emitted from the light emitting layer. A light exit surface of the light emitting layer may include a first light exit region and a second light exit region having lower luminance than a luminance of the first light exit region. The barrier layer may have a greater thickness in a region thereof surrounding the second light exit region than a thickness in a region thereof surrounding the first light exit region. Further, the thickness of the barrier layer may correspond to a distance from an inner side surface of the barrier layer to an outer side surface thereof.

An upper surface of the barrier layer may include a first upper surface adjacent to the first light exit region and a second upper surface adjacent the second light exit region. Each of the first upper surface and the second upper surface may include a first end coupled with the wavelength conversion layer and a second end placed opposite the first end. Here, the first end and the second end of each of the first upper surface and the second upper surface may be placed higher than the upper surface of the light emitting layer.

An upper surface of the barrier layer may include a curved surface.

The light emitting apparatus of the vehicle may further include a blocking layer surrounding a side surface of the barrier layer. The blocking layer may be configured to absorb the light emitted from the light emitting layer.

Embodiments of the present invention provide a light emitting apparatus that can improve luminance uniformity through compensation for luminance unevenness.

Embodiments of the present invention provide a light emitting apparatus that can improve luminance uniformity.

Embodiments of the present invention provide a light emitting apparatus that can realize a narrow beam angle.

### BRIEF DESCRIPTION OF THE DRAWINGS

FIG. 1 is a perspective view of a light emitting apparatus according to a first embodiment of the present invention.

FIG. 2 is a front view of the light emitting apparatus according to the first embodiment of the present invention.

FIG. 3 is a cross-sectional view (A1-A2) of the light emitting apparatus according to the first embodiment of the present invention shown in FIG. 1.

FIG. 4 is a front view of a light emitting apparatus according to a second embodiment of the present invention.

FIG. 5 is a cross-sectional view (B1-B2) of the light emitting apparatus according to the second embodiment of the present invention shown in FIG. 4.

FIG. 6 is another cross-sectional view (B3-B4) of the light emitting apparatus according to the second embodiment of the present invention shown in FIG. 4.

FIG. 7 is a front view of a light emitting apparatus according to a third embodiment of the present invention.

FIG. 8 is a cross-sectional view (C1-C2) of the light emitting apparatus according to the third embodiment of the present invention shown in FIG. 7.

FIG. 9 is a sectional view of a light emitting apparatus according to a fourth embodiment of the present invention.

FIG. 10 is a sectional view of a light emitting apparatus according to a fifth embodiment of the present invention.

FIG. 11 is a sectional view of a light emitting apparatus according to a sixth embodiment of the present invention.

FIG. 12 is a sectional view of a light emitting apparatus according to a seventh embodiment of the present invention.

FIG. 13 is a sectional view of a light emitting apparatus according to an eighth embodiment of the present invention.

FIG. 14 is a sectional view of a light emitting apparatus according to a ninth embodiment of the present invention.

FIG. 15 is an exemplary view of a vehicle including a light emitting apparatus according to an embodiment of the present invention.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” or the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), or the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, or the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, light emitting apparatuses according to the present invention will be described in detail with reference to the drawings.

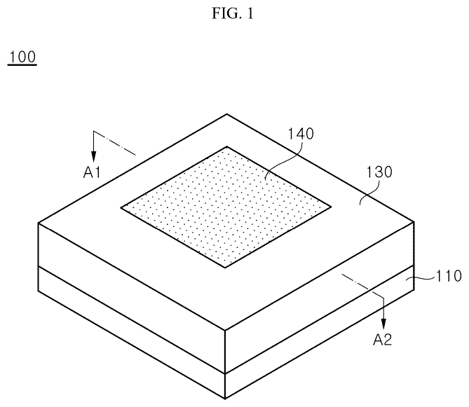

FIG. 1 to FIG. 3 relate to a light emitting apparatus according to a first embodiment of the present invention.

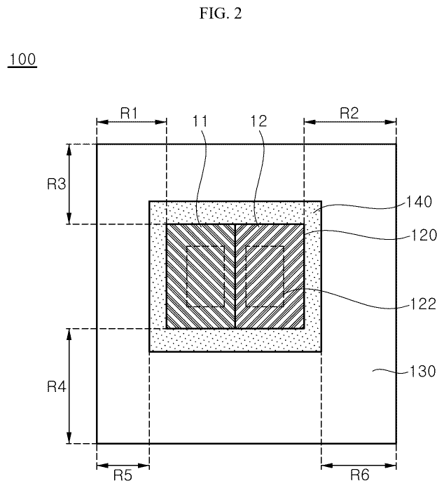

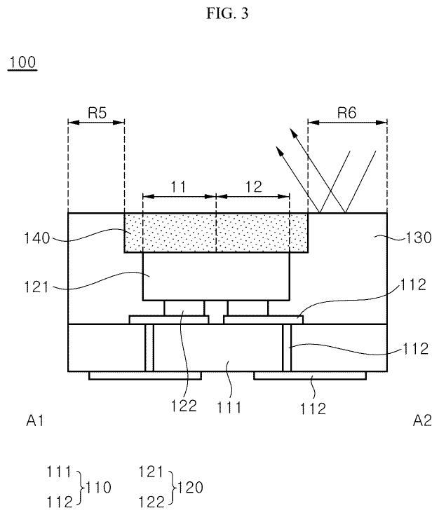

FIG. 1 is a perspective view of a light emitting apparatus according to the first embodiment of the present invention. FIG. 2 is a front view of the light emitting apparatus according to the first embodiment of the present invention. FIG. 3 is a cross-sectional view (A1-A2) of the light emitting apparatus according to the first embodiment of the present invention shown in FIG. 1.

Referring to FIG. 1 to FIG. 3, a light emitting apparatus 100 according to a first embodiment may include a substrate 110, a light emitting layer 120, a wavelength conversion layer 140, and a barrier layer 130.

The substrate 110 may include a substrate base 111 and an electrically conductive pattern 112.

The substrate base 111 may be formed of at least a material of a phenolic resin, an epoxy resin, a polyimide resin, or ceramics. That is, the substrate base 111 may be formed of an insulating material. In addition, the substrate base 111 may include a metal layer and an insulating layer formed on a surface of the metal layer. For example, the insulating layer may be formed of a metallic oxide, a ceramic, or an insulating resin including a phenolic resin, an epoxy resin, or PTFE (Polytetrafluoroethylene). That is, the substrate base 111 may be formed in a structure that can be insulated from the electrically conductive pattern 112. However, it should be understood that the substrate base 111 is not limited to the above materials and structure, and may be formed of various materials or in various structures that can be insulated from the electrically conductive pattern 112.

The substrate base 111 may further include ceramic fillers. When the substrate base 111 includes the ceramic fillers, the light emitting apparatus 100 can have improved heat dissipation efficiency and the substrate 110 can have improved light reflectivity.

The electrically conductive pattern 112 may be formed on upper and lower surfaces of the substrate base 111. In addition, the electrically conductive pattern 112 may be further formed on an inner or side surface of the substrate base 111 to electrically connect the electrically conductive pattern 112 formed on the upper surface of the substrate base 111 to the electrically conductive pattern 112 formed on the lower surface of the substrate base 111. The electrically conductive pattern 112 may be formed of any electrically conductive material. By way of example, the electrically conductive pattern 112 may be formed of at least a material of Cu, W, Ag, Au, Ni, or Pd. When the electrically conductive pattern 112 is formed of a metal, the light emitting apparatus 100 can have improved heat dissipation efficiency.

The electrically conductive pattern 112 of the substrate 110 is electrically connected to the light emitting layer 120 and the substrate 110 can supply power to the light emitting layer 120 through the electrically conductive pattern 112.

The light emitting layer 120 can generate and emit light by receiving electric power supplied from the substrate 110. According to this embodiment, the light emitting layer 120 may include a light emitting diode chip including a light emitting structure 121 and electrodes 122.

The light emitting structure 121 generates light upon receiving electric power. For example, the light emitting structure 121 may include semiconductor layers, such as a first semiconductor layer, a second semiconductor layer, and an active layer.

The first semiconductor layer may be formed of a compound semiconductor, such as a Group III-V semiconductor compound, a Group II-VI semiconductor compound, and the like. For example, the first semiconductor layer may be an n-type semiconductor layer doped with an n-type dopant.

The second semiconductor layer may be formed of a compound semiconductor, such as a Group III-V semiconductor compound, a Group II-VI semiconductor compound, and the like. For example, the second semiconductor layer may be a p-type semiconductor layer doped with a p-type dopant.

By way of example, the first semiconductor layer is an n-type semiconductor layer and the second semiconductor layer is a p-type semiconductor layer. Alternatively, the first semiconductor layer may be a p-type semiconductor layer and the second semiconductor layer may be an n-type semiconductor layer.

The active layer may be formed between the first semiconductor layer and the second semiconductor layer.

The active layer refers to a layer in which electrons injected through the first semiconductor layer recombine with holes injected through the second semiconductor layer, and can generate light through recombination of the electrons and the holes. Alternatively, the active layer can generate light through recombination of holes injected through the first semiconductor layer and electrons injected through the second semiconductor layer.

The active layer may be formed in any one of a single well structure, a multi-well structure, a single quantum well structure, a multi-quantum well (MQW) structure, a quantum dot structure, or a quantum line structure.

Light generated by the active layer can be emitted to the outside of the light emitting structure 121 through upper and side surfaces of the light emitting structure 121. In addition, light generated by the active layer may be emitted to the outside of the light emitting structure 121 through a lower surface of the light emitting structure 121.

Depending on the composition of the first semiconductor layer, the second semiconductor layer, and the active layer, the type of light generated therein can vary. For example, the light emitting structure 121 may generate and emit blue light or UV light. The type of light emitted from the light emitting structure 121 is not limited to blue light and UV light, and the light emitting structure 121 may emit light with various wavelengths.

The light emitting layer 120 may further include a growth substrate for growth of semiconductor layers. For example, the growth substrate may be formed of a material selected from among sapphire (Al₂O₃), SiC, GaAs, GaN, ZnO, Si, GaP, InP, and Ge.

In the light emitting layer 120, the semiconductor layers may be electrically connected to the electrically conductive pattern 112 of the substrate 110 through a plurality of electrodes 122. For example, the light emitting layer 120 may include the plurality of electrodes 122. Here, an electrode 122 may be electrically connected to the first semiconductor layer and another electrode 122 may be electrically connected to the second semiconductor layer. The electrodes 122 may be formed of a conductive material, such as a metal, a conductive paste, and the like.

The wavelength conversion layer 140 may be formed on top of the light emitting layer 120.

The wavelength conversion layer 140 may include a base and a wavelength conversion material dispersed in at least a region within the base.

The base may be formed of a material through which light from the light emitting layer 120 is transmitted. For example, the base may be formed of a polymer resin, such as a silicone resin, an epoxy resin, or a ceramic material, such as glass, sapphire, and alumina. In addition, the base may have a transmittance of 70% or more. Thus, the wavelength conversion layer 140 or the base of the wavelength conversion layer 140 may absorb less light emitted from the light emitting layer 120, thereby improving luminous efficacy of the light emitting apparatus 100.

The wavelength conversion material can convert the wavelength of light emitted from the light emitting layer 120. That is, the wavelength conversion material can excite light emitted from the light emitting layer 120 to emit light in a different wavelength band than the light emitted from the light emitting layer 120. By way of example, the wavelength conversion layer 140 may include at least a wavelength conversion material for converting a wavelength in a first region, which corresponds to the wavelength of light emitted from the light emitting layer 120. The wavelength conversion material may include at least a particle of a first type of particle for converting the wavelength in the first region into a wavelength in a second region or a second type of particle for converting the wavelength in the first region into a wavelength in a third region. The wavelength in the first region may be a shorter wavelength than the wavelength in the second region and the wavelength in the third region may be a longer wavelength than the wavelength in the second region. In addition, a peak wavelength of the wavelength of the first region may be smaller than a peak wavelength of the wavelength of the second region, and a peak wavelength of the wavelength of the third region may be greater than the peak wavelength of the wavelength of the second region. For example, the wavelength in the first region may be a wavelength in the blue region, the wavelength in the second region may be a wavelength in the yellow or green region, and the wavelength in the third region may be a wavelength in the red region.

The wavelength conversion material may include at least a material of phosphor particles, quantum dots, or organic dyes. For example, the first type of particle may refer to wavelength conversion particles that emit light having a peak wavelength in the green light or yellow light band and may include at least a material of quantum dots, LuAG series, YAG series, beta-SiAlON series, nitride series, silicate series, halophosphide series, or oxynitride series. The second type of particle may refer to red wavelength conversion particles that emit light having a peak wavelength in the red light band, and may include at least a material of quantum dots, nitride series, such as CASN, CASON, or SCASN, silicate series, sulfide series, fluoride series, or oxynitride series. However, it should be understood that the first type of particle and the second type of particle are not limited thereto.

The barrier layer 130 may be formed on the substrate 110 to cover side surfaces of the light emitting layer 120 and the wavelength conversion layer 140.

The barrier layer 130 may be formed of an insulating material. For example, the barrier layer 130 may be formed of a ceramic material or an insulating resin, such as a silicone resin, a polyimide resin, a urethane resin, a polymer resin, and the like.

In addition, the barrier layer 130 may include a light reflective material. For example, the light reflective material may include a variety of light reflective materials, such as TiO₂, Ba₂Ti₉O₂₀, BaSO₄, SiO₂, CaCO₃, ZnO, CaCO₃, and the like. Further, the light reflective material may have a reflectivity of 80% or more for visible light.

The barrier layer 130 may reflect light emitted from the side surfaces of the light emitting layer 120, the wavelength conversion layer 140, and an optical layer to allow the light to be emitted from the light emitting apparatus 100 through an upper surface of the optical layer.

A light exit surface of the light emitting layer 120 may be an upper surface of the light emitting layer 120, which faces the wavelength conversion layer 140, and side surfaces of the light emitting layer 120. However, since the side surfaces of the light emitting layer 120 are covered by the barrier layer 130, light emitted from the side surfaces of the light emitting layer 120 may be reflected from the barrier layer 130 and emitted through the upper surface of the light emitting layer 120. Here, the side surfaces or the upper surface of the light emitting layer 120 may have lower light reflectivity than the barrier layer 130. In addition, the upper surface of the light emitting layer 120 may have higher light transmittance than the barrier layer 130. As a result, light emitted from the side surfaces of the light emitting layer 120 may be reflected from the barrier layer 130 to be emitted through the upper surface of the light emitting layer 120 instead of being emitted through the barrier layer 130.

A light emitting diode chip corresponding to the light emitting layer 120 may have uneven luminance on a light exit surface thereof for various reasons. The light emitting apparatus 100 according to the embodiment of the present invention can improve luminance uniformity of the light emitting layer 120 using the barrier layer 130. For example, in the light emitting apparatus 100, a region of the barrier layer 130 placed near a low-luminance region of the light emitting layer 120 may have a greater thickness than a region of the barrier layer 130 placed near a high-luminance region of the light emitting layer 120. The thickness of the barrier layer 130 may be inversely proportional to luminance of the light emitting layer 120 adjacent thereto. Accordingly, low luminance of the light emitting layer 120 can be compensated for by improving efficiency of light reflection by the barrier layer 130 in the low-luminance region of the light emitting layer 120.

For example, the light exit surface of the light emitting layer 120 may be divided into a first light exit region 11 and a second light exit region 12. Although the light emitting layer 120 may emit light through the upper surface and the side surfaces thereof, a main light exit surface of the light emitting layer 120 is the upper surface thereof. Accordingly, the first light exit region 11 and the second light exit region 12 of the light emitting layer 120 are placed on the upper surface of the light emitting layer 120. Luminance in the first light exit region 11 may be higher than luminance in the second light exit region 12.

According to this embodiment, with reference to the same vertical line or the same horizontal line, a region of the barrier layer 130 adjacent the second light exit region 12 may have a greater thickness than a region of the barrier layer 130 adjacent the first light exit region 11. The thickness of the barrier layer 130 may be inversely proportional to luminance of the light exit region of the light emitting layer 120 adjacent thereto. Here, the same vertical line and the same horizontal line are based on a front view of the light emitting apparatus 100. This description will be equally applied to other embodiments.

Referring to FIG. 2, with reference to the same horizontal line, a thickness R2 of a region of the barrier layer 130 surrounding the second light exit region 12 is greater than a thickness R1 of a region of the barrier layer 130 surrounding the first light exit region 11, which has higher luminance than the second light exit region 12. For example, the thickness R2 of a region of the barrier layer 130 surrounding the second light exit region 12 may be 5% or more greater than the thickness R1 of a region of the barrier layer 130 surrounding the first light exit region 11. In addition, with reference to the same vertical line, a thickness R4 of a region of the barrier layer 130 surrounding the second light exit region 12 is greater than a thickness R3 of a region of the barrier layer 130 surrounding the first light exit region 11, which has higher luminance than the second light exit region 12. For example, the thickness R4 of a region of the barrier layer 130 surrounding the second light exit region 12 may be 5% or more greater than the thickness R3 of a region of the barrier layer 130 surrounding the first light exit region 11. In addition, a region of the barrier layer 130 surrounding the second light exit region 12 may have a larger area than a region of the barrier layer 130 surrounding the first light exit region 11. For example, the area of a region of the barrier layer 130 surrounding the second light exit region 12 may be 10% or more larger than the area of a region of the barrier layer 130 surrounding the first light exit region 11. Accordingly, the barrier layer 130 has higher light reflectivity in a region thereof surrounding the second light exit region 12 than in a region thereof surrounding the first light exit region 11.

As such, light reflectivity of the light emitting apparatus 100 according to this embodiment can be improved by the structure in which a region of the barrier layer 130 surrounding the second light exit region 12, which has lower luminance than a region of the barrier layer 130 surrounding the first light exit region 11 of the light emitting layer 120, has a greater thickness than the barrier layer 130 surrounding the first light exit region 11 of the light emitting layer 120. Thus, the light emitting apparatus 100 according to this embodiment can reduce difference in luminance between the first light exit region 11 and the second light exit region 12 by increasing the quantity of light emitted from the second light exit region 12 through increase in light reflectivity in the vicinity of the second light exit region 12.

In addition, the light emitting apparatus 100 according to this embodiment has a difference between a width R5 of an upper surface of the barrier layer 130 surrounding the first light exit region 11 and a width R6 of an upper surface of the barrier layer 130 surrounding the second light exit region 12. Referring to FIG. 3, the width R6 of the upper surface of the barrier layer 130 surrounding the second light exit region 12 is greater than the width R5 of the upper surface of the barrier layer 130 surrounding the first light exit region 11. For example, the width of the upper surface of the barrier layer 130 surrounding the second light exit region 12 may be 5% or more larger than the width of the upper surface of the barrier layer 130 surrounding the first light exit region 11. Furthermore, an area of the upper surface of the barrier layer 130 surrounding the second light exit region 12 may be 10% or more larger than an area of the upper surface of the barrier layer 130 surrounding the first light exit region 11. That is, the upper surface of the barrier layer 130 surrounding the second light exit region 12 has a larger light reflective area than the upper surface of the barrier layer 130 surrounding the first light exit region 11. Thus, the light emitting apparatus 100 according to this embodiment can reflect more light from the upper surface of the barrier layer 130 surrounding the second light exit region 12 of the barrier layer 130 than from the upper surface of the barrier layer 130 surrounding the first light exit region 11 thereof. Thus, the light emitting apparatus 100 according to this embodiment can reduce difference in luminance between the first light exit region 11 and the second light exit region 12 by increasing the quantity of light directed toward the upper direction of the second light exit region 12.

As such, in the light emitting apparatus 100 according to this embodiment, a region of the barrier layer 130 surrounding a light exit region having low luminance on the light exit surface of the light emitting layer 120 is formed thicker than a region of the barrier layer surrounding the other light exit region. Thus, the light emitting apparatus 100 according to this embodiment can increase light reflectivity on an inner side surface and the upper surface of the barrier layer 130 in the light exit region of the light emitting layer 120 having low luminance. Thus, the light emitting apparatus 100 according to this embodiment can improve luminance uniformity in the light exit region thereof.

Next, light emitting apparatuses according to various embodiments will be described. In the following description, description of the same components as the above embodiment will be omitted. For the omitted description, refer to description of the same components in the above embodiment.

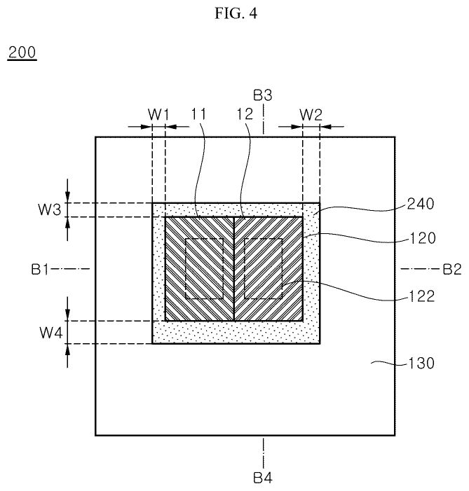

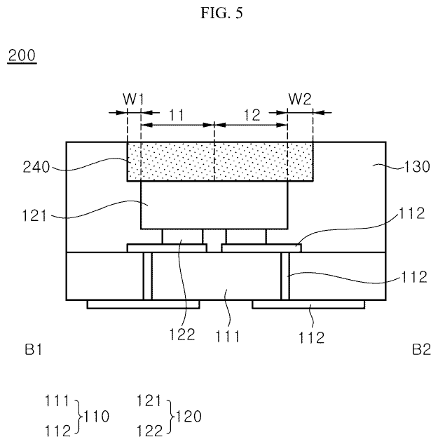

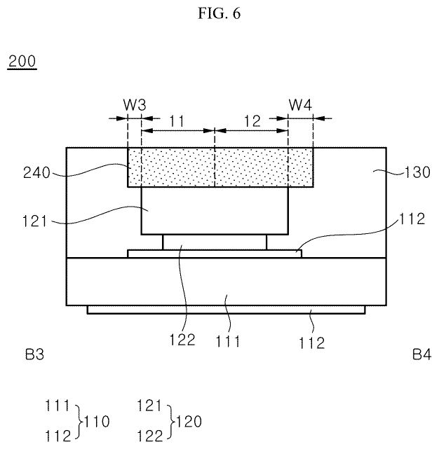

FIG. 4 to FIG. 6 are views of a light emitting apparatus according to a second embodiment of the present invention. FIG. 4 is a front view of the light emitting apparatus according to the second embodiment of the present invention. FIG. 5 is a cross-sectional view (B1-B2) of the light emitting apparatus according to the second embodiment shown in FIG. 4. FIG. 6 is another cross-sectional view (B3-B4) of the light emitting apparatus according to the second embodiment shown in FIG. 4.

Referring to FIG. 4 to FIG. 6, a light emitting apparatus 200 according to a second embodiment may include a substrate 110, a light emitting layer 120, a wavelength conversion layer 240, and a barrier layer 130.

The wavelength conversion layer 240 is formed to cover the upper surface of the light emitting layer 120. In addition, the wavelength conversion layer 240 may have a larger cross-sectional area than the light emitting layer 120. Thus, the wavelength conversion layer 240 may cover the entirety of the upper surface of the light emitting layer 120. As shown in FIG. 5 and FIG. 6, the wavelength conversion layer 240 may have a larger area than the light emitting layer 120 and may have a side surface placed farther outwards than a side surface of the light emitting layer 120. In other words, at least a surface of the wavelength conversion layer 240 may have a greater length than at least a surface of the light emitting layer 120.

According to this embodiment, with reference to the same vertical line or the same horizontal line, a width from an outer side surface of the second light exit region 12 to an end of the wavelength conversion layer 240 may be greater than a width from an outer side surface of the first light exit region 11 to the other end of the wavelength conversion layer 240. In addition, the end of the wavelength conversion layer 240 may correspond to a periphery or side surface of the upper surface of the wavelength conversion layer 240 adjacent the second light exit region 12 and placed farther outwards than the outer side surface of the second light exit region 12. Further, the other end of the wavelength conversion layer 240 may correspond to a periphery or side surface of the upper surface of the wavelength conversion layer 240 adjacent the first light exit region 11 and placed farther outwards than the outer side surface of the first light exit region 11. Here, the end of the wavelength conversion layer 240, the other end of the wavelength conversion layer 240, the outer side surface of the first light exit region 11, and the outer side surface of the second light exit region 12 may be placed side by side.

Referring to FIG. 4, with reference to the same horizontal line, a width W2 of the wavelength conversion layer 240 placed outside the second light exit region 12 is greater than a width W1 of the wavelength conversion layer 240 placed outside the first light exit region 11, which has higher luminance than the second light exit region 12. For example, the width W2 of the wavelength conversion layer 240 placed outside of the second light exit region 12 may be 10% or more wider than the width W1 of the wavelength conversion layer 240 placed outside the first light exit region 11.

In addition, with reference to the same vertical line, a width W4 of the wavelength conversion layer 240 at a side of the light emitting layer 120 may be greater than a width W3 of the wavelength conversion layer 240 at the other side of the light emitting layer 120, or vice versa. Comparing luminance at a side of the light emitting layer 120 with luminance at the other side thereof with reference to a vertical line, the wavelength conversion layer 240 placed outside a low-luminance region may be formed to have a greater width than the wavelength conversion layer 240 placed outside a high-luminance region. For example, the width of the wavelength conversion layer 240 placed outside the low-luminance region may be 10% or more greater than the width of the wavelength conversion layer 240 placed outside the high-luminance region.

As such, the wavelength conversion layer 240 has a larger cross-sectional area in a region thereof covering the second light exit region 12 and the outer side surface of the second light exit region 12 than in a region thereof covering the first light exit region 11 and the outer side surface of the first light exit region 11.

Accordingly, the wavelength conversion layer 240 allows emission of light through a larger area at an upper portion of the second light exit region 12 having lower luminance than the first light exit region 11. Thus, the light emitting apparatus 200 according to this embodiment can reduce difference in luminance between an upper portion of the first light exit region 11 and the upper portion of the second light exit region 12 through increase in quantity of light by emitting light through a larger area at the upper portion of the second light exit region 12 having lower luminance than the first light exit region 11. Here, the upper surface of the wavelength conversion layer acting as a light exit surface or light exit region thereof is the light exit surface of the light emitting apparatus 200.

Accordingly, the light emitting apparatus 200 according to this embodiment can improve luminance uniformity through the wavelength conversion layer 240 even when the first light exit region 11 and the second light exit region 12 of the light emitting layer 120 have uneven luminance.

Furthermore, in the light emitting apparatus 200 according to this embodiment, a region of the barrier layer 130 surrounding the light exit region having low luminance on the light exit surface of the light emitting layer 120 may be formed thicker than a region thereof surrounding the other light exit region. In the light emitting apparatus 200, light reflectivity can be increased through a relatively thick side surface of the barrier layer 130 and thus a relatively wide upper surface thereof, thereby enabling compensation for the quantity of light directed in an upward direction of the light exit region of the light emitting layer 120 having low luminance. Thus, the light emitting apparatus 200 can improve luminance uniformity through the barrier layer 130.

As such, the light emitting apparatus 200 according to this embodiment can improve luminance uniformity of the light emitting apparatus 200 by compensating for uneven luminance of the light emitting layer 120 through not only the barrier layer 130 but also the wavelength conversion layer 240.

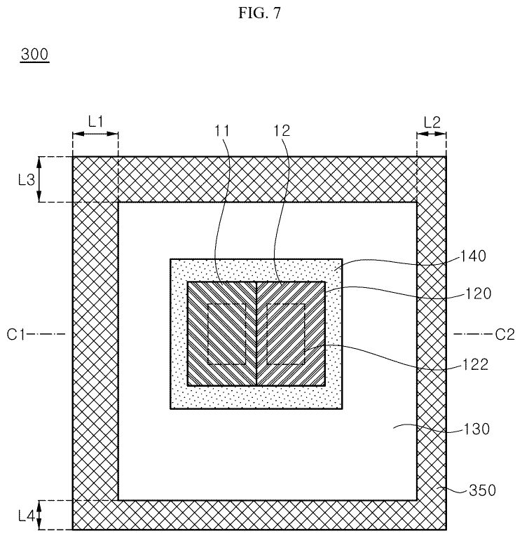

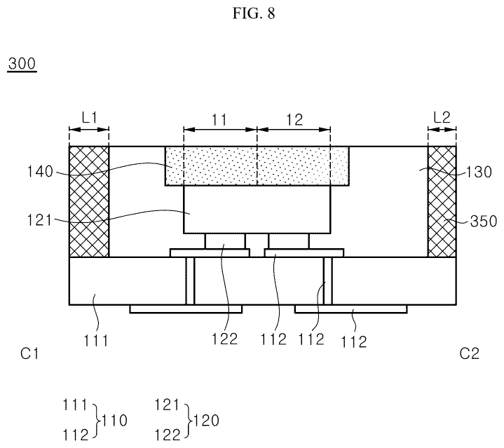

FIG. 7 and FIG. 8 are views of a light emitting apparatus according to a third embodiment of the present invention. FIG. 7 is a front view of the light emitting apparatus according to the third embodiment of the present invention and FIG. 8 is a cross-sectional view (C1-C2) of the light emitting apparatus according to the third embodiment of the present invention shown in FIG. 7.

Referring to FIG. 7 and FIG. 8, a light emitting apparatus 300 according to a third embodiment may include a substrate 110, a light emitting layer 120, a wavelength conversion layer 140, a barrier layer 130, and a blocking layer 350.

According to this embodiment, the blocking layer 350 may cover at least a surface of outer side surfaces of the barrier layer 130.

The blocking layer 350 may be formed of a material that can block light. For example, the blocking layer 350 may be formed by dispersing light-blocking particles such as carbon black, a black dye, silica, metal oxides, such as iron oxide, titanium dioxide, zinc oxide, and titanium dioxide, pigments, nanoparticles, and the like in a thermoplastic resin, such as PCT and PPA, or a thermosetting resin, such as EMC (epoxy molding compound, silicone). The blocking layer 350 may also be formed using metallic materials, such as Cu, Al, Fe, and the like.

The blocking layer 350 may disposed on the outer side surfaces of the barrier layer 130 and serve to absorb light passing through the barrier layer 130 to prevent light from escaping the light emitting apparatus 300. In addition, the blocking layer 350 may block a fraction of light reflected from the barrier layer 130 or the wavelength conversion layer 140 to reduce light interference and focus light. Here, the light blocking layer 350 may have lower transmittance than the barrier layer 130. Preferably, the light blocking layer 350 has a transmittance of less than 20%.

Referring to FIG. 7 and FIG. 8, the blocking layer 350 is formed such that a region of the blocking layer 350 adjacent the first light exit region 11 having relatively high luminance has a greater thickness than a region thereof adjacent the second light exit region 12 having relatively low luminance. Here, the thickness of the blocking layer 350 refers to a distance from an inner side surface of the blocking layer 350 adjoining the barrier layer 130 to an outer side surface thereof.

Referring to FIG. 7, with reference to the same horizontal line, a thickness L2 of a region of the blocking layer 350 surrounding the second light exit region 12 is thinner than a thickness L1 of a region of the blocking layer 350 surrounding the first light exit region 11 that has higher luminance than the second light exit region 12. For example, the thickness L1 of a region of the blocking layer 350 surrounding the first light exit region 11 may be 3% or more greater than the thickness L2 of a region of the blocking layer 350 surrounding the second light exit region 12.

Furthermore, with reference to the same vertical line, a thickness L4 of a region of the blocking layer 350 formed at a side of the barrier layer 130 is thinner than a thickness L3 of a region of the blocking layer 350 formed at the other side of the barrier layer 130, or vice versa. By comparing luminance at a side of the light emitting layer 120 or the wavelength conversion layer 140 with luminance at the other side thereof with reference to the vertical line, a region of the blocking layer 350 placed outside a high-luminance region may be formed to have a greater thickness than a region of the blocking layer 350 placed outside a low-luminance region. For example, the thickness of a region of the blocking layer 350 placed outside the high-luminance region may be 3% or more greater than the thickness of a region of the blocking layer 350 surrounding the low-luminance region. In addition, the area of a region of the blocking layer 350 placed outside the high-luminance region may be 5% or more larger than the area of a region of the blocking layer 350 surrounding the low-luminance region.

The barrier layer 130 surrounding the second light exit region 12 is thicker than the barrier layer 130 surrounding the first light exit region 11 and thus has relatively high light reflectivity. Thus, a greater quantity of light can be emitted from the light emitting apparatus 300 through a thin region of the barrier layer 130, which has relatively low light reflectivity, than a thicker region of the barrier layer 130. Here, the blocking layer 350 is formed to cover the side surfaces of the barrier layer 130 and thus can absorb light having passed through the side surfaces of the barrier layer 130. Further, the quantity of light passing through the blocking layer 350 and emitted to the outside can be reduced as the thickness of the blocking layer 350 increases.

Accordingly, the blocking layer 350 may be formed to have a greater thickness in the thin region of the barrier layer 130 than in the thick region of the barrier layer 130 to effectively absorb light that has passed through the barrier layer 130 having a relatively thin thickness, thereby preventing light from being emitted through the side surfaces of the light emitting apparatus 300.

In addition, the barrier layer 130 may be thicker than the blocking layer 350 and may be formed to have a larger cross-sectional area than the blocking layer 350 to increase the quantity of light.

The light emitting apparatus 300 according to this embodiment can prevent light from being emitted from the side surfaces thereof other than the light exit surface thereof by the blocking layer 350. That is, the light emitting apparatus 300 according to this embodiment ensures that light can be emitted only through a specific region, that is, the light exit surface.

Referring to FIG. 8, the blocking layer 350 is formed such that an upper surface of the blocking layer 350 is flush with the upper surfaces of the wavelength conversion layer 140 and the barrier layer 130. However, it should be understood that the structure of the blocking layer 350 is not limited thereto.

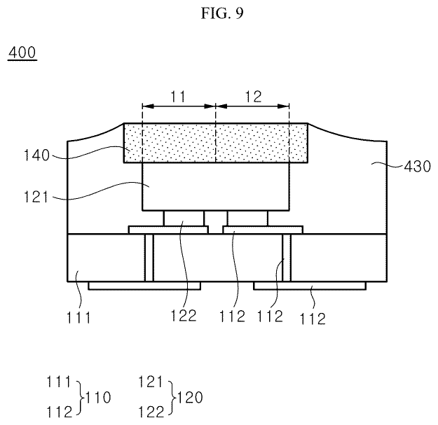

FIG. 9 is a sectional view of a light emitting apparatus according to a fourth embodiment of the present invention.

Referring to FIG. 9, a light emitting apparatus 400 according to a fourth embodiment may include a substrate 110, a light emitting layer 120, a wavelength conversion layer 140, and a barrier layer 430.

The barrier layer 430 of the light emitting apparatus 400 according to this embodiment has a different structure from the barrier layers 130 according to the above embodiments (FIG. 1 to FIG. 8).

Referring to FIG. 9, the upper surface of the barrier layer 430 may have an inclined structure. More specifically, the upper surface of the barrier layer 430 has a height gradually decreasing from an end, which corresponds to an inner side edge thereof close to the wavelength conversion layer 140, to the other end, which corresponds to an outer side edge thereof. Here, the other end of the upper surface of the barrier layer 430 is placed opposite the end of the upper surface thereof. Here, the height of the other end of the upper surface of the barrier layer 430 may be greater than the height of the upper surface of the light emitting layer 120. With a structure in which a region of the barrier layer 430 having a gradually decreasing thickness is placed above the light emitting layer 120, the side surface of the light emitting layer 120 ensures that the barrier layer 430 has a sufficient thickness. Accordingly, the light emitting apparatus 400 can prevent light leakage from the side surfaces thereof due to light emitted from the side surfaces of the light emitting layer 120 and having passed through the barrier layer 430.

In addition, the upper surface of the barrier layer 430 may include a curved surface.

In the light emitting apparatus 400 according to this embodiment, the upper surface of the barrier layer 430 includes an inclined and curved surface, whereby light colliding the upper surface of the barrier layer 430 can be more concentrated in an upward direction of the light emitting apparatus 400 than in a structure in which the upper surface of the barrier layer 430 is flat.

Furthermore, since the upper surface of the barrier layer 430 according to this embodiment includes the inclined and curved surface, the upper surface of the barrier layer 430 has a larger area even if the barrier layer 430 according to this embodiment has the same thickness as the barrier layer 430 with a flat upper surface. Thus, the barrier layer 430 according to this embodiment can reflect more light from the upper surface thereof in the upward direction of the light emitting apparatus 400 than the barrier layer 430 with the flat upper surface.

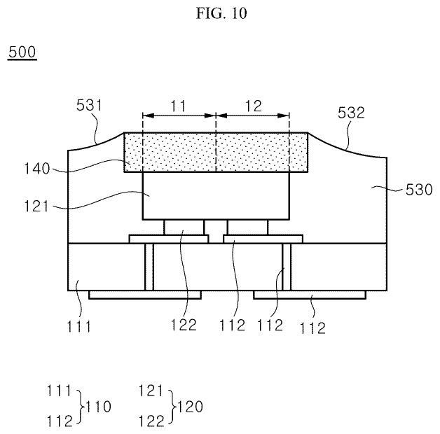

FIG. 10 is a sectional view of a light emitting apparatus according to a fifth embodiment of the present invention.

Referring to FIG. 10, a light emitting apparatus 500 according to a fifth embodiment may include a substrate 110, a light emitting layer 120, a wavelength conversion layer 140, and a barrier layer 530.

In the light emitting apparatus 500 according to this embodiment, the barrier layer 530 may have a structure including an inclined and curved surface. In this embodiment, the barrier layer 530 may have different structures on both sides of an upper surface thereof relative to the wavelength conversion layer 140.

For example, the upper surface of the barrier layer 530 adjacent the first light exit region 11 may be referred to as a first upper surface 531 and the upper surface of the barrier layer 530 adjacent the second light exit region 12 may be referred to as a second upper surface 532.

Each of the first upper surface 531 and the second upper surface 532 of the barrier layer 530 has a height gradually decreasing from an end, which corresponds to an inner side edge thereof adjoining the wavelength conversion layer 140, to the other end, which corresponds to an outer side edge thereof. Here, the height of each of the other end of the first upper surface 531 and the other end of the second upper surface 532 of the barrier layer 530 may be greater than the height of the upper surface of the light emitting layer 120. Further, the height of the other end of the second upper surface 532 of the barrier layer 530 may be lower than the height of the other end of the first upper surface 531. Thus, in the barrier layer 530, the second upper surface 532 adjacent the second light exit region 12 having relatively low luminance may have a larger area than the first upper surface 531 adjacent the first light exit region 11 having relatively high luminance.

With such a structure, the barrier layer 530 can reflect more light over a larger area on the second upper surface 532 than on the first upper surface 531. Thus, the light emitting apparatus 500 according to this embodiment can increase the quantity of light directed toward a relatively low-luminance region by the barrier layer 530, thereby reducing difference between a low-luminance region and a high-luminance region, thereby resolving luminance imbalance.

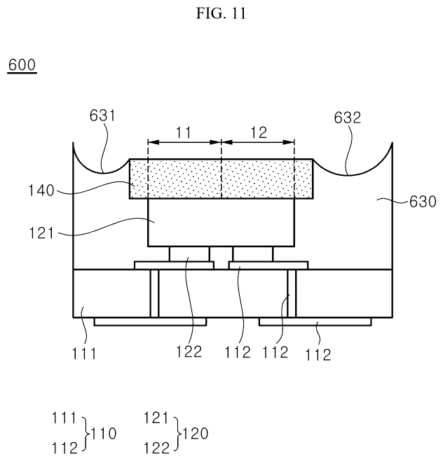

FIG. 11 is a sectional view of a light emitting apparatus according to a sixth embodiment of the present invention.

Referring to FIG. 11, a light emitting apparatus 600 according to a sixth embodiment may include a substrate 110, a light emitting layer 120, a wavelength conversion layer 140, and a barrier layer 630.

In the light emitting apparatus 600 according to this embodiment, the barrier layer 630 may have a curved structure in which an upper surface is concave in a downward direction. With such a structure, the upper surface of the barrier layer 630 may have a larger area than an upper surface inclined in one direction. That is, the upper surface of the barrier layer 630 can reflect more light directed in the downward direction or toward the upper surface of the barrier layer 630.

In addition, according to this embodiment, the lowest height of the second upper surface 632 of the barrier layer 630 may be greater than the lowest height of the first upper surface 631 thereof. Thus, the second upper surface 632 may have a larger radius of curvature than the first upper surface 631. That is, since the second upper surface 632 of the barrier layer 630 has a larger area than the first upper surface 631 thereof, the second upper surface 632 can have higher light reflectivity than the first upper surface 631. The radius of curvature of the first upper surface 631 may be adjusted to be greater than the radius of curvature of the second upper surface 632 by increasing the thickness of the barrier layer 630 under the first upper surface 631.

Since the barrier layer 630 according to this embodiment has a concave upper surface, light reflected from a region of the barrier layer 630 adjacent the outer side of the upper surface thereof can be effectively focused to a center of the light exit surface of the light emitting apparatus 600.

The light emitting apparatuses 400, 500, 600 according to the fourth to sixth embodiments of the present invention shown in FIG. 9 to FIG. 11 can improve luminance uniformity through the barrier layers 430, 530, 630 each having different thicknesses on both sides thereof relative to the light emitting layer while increasing the quantity of light through the barrier layers 430, 530, 630 each having an inclined and curved upper surface.

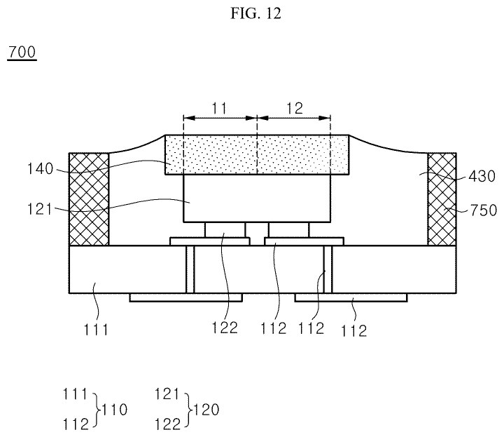

FIG. 12 is a sectional view of a light emitting apparatus according to a seventh embodiment of the present invention.

Referring to FIG. 12, the upper surface of the barrier layer 430 may have an inclined structure. More specifically, the upper surface of the barrier layer 430 has a height gradually decreasing from an end, which corresponds to an inner side edge thereof close to the wavelength conversion layer 140, to the other end, which corresponds to an outer side edge thereof. Here, the other end of the upper surface of the barrier layer 430 is placed opposite the end of the upper surface thereof. Here, the height of the other end of the upper surface of the barrier layer 430 may be greater than the height of the upper surface of the light emitting layer 120. With a structure in which a region of the barrier layer 430 having a gradually decreasing thickness is placed above the light emitting layer 120, the side surface of the light emitting layer 120 ensures that the barrier layer 430 has a sufficient thickness. Accordingly, the light emitting apparatus 700 can prevent light leakage from the side surfaces thereof due to light emitted from the side surfaces of the light emitting layer 120 and transmitted through the barrier layer 430. Furthermore, the blocking layer 750 may have an upper surface placed higher than the upper surface of the light emitting layer 120 to prevent light having passed through the barrier layer 430 from being emitted from the side surfaces of the light emitting apparatus 700.

In addition, the upper surface of the barrier layer 430 may include a curved surface.

In the light emitting apparatus 700 according to this embodiment, the upper surface of the barrier layer 430 includes an inclined and curved surface, whereby light colliding the upper surface of the barrier layer 430 can be more concentrated in the upward direction of the light emitting apparatus 400 than in a structure in which the upper surface of the barrier layer 430 is flat.

Furthermore, since the upper surface of the barrier layer 430 according to this embodiment includes the inclined and curved surface, the upper surface of the barrier layer 430 has a larger area even if the barrier layer 430 according to this embodiment has the same thickness as the barrier layer with a flat upper surface. Accordingly, the barrier layer 430 according to this embodiment can reflect more light from the upper surface thereof in the upward direction of the light emitting apparatus 400 than the barrier layer with the flat upper surface.

In this embodiment, the blocking layer 750 has a structure in which the upper surface of the blocking layer 750 is lower than the upper surface of the wavelength conversion layer 140 and higher than the light emitting layer 120. However, it should be understood that the structure of the blocking layer 750 according to this embodiment is not limited thereto.

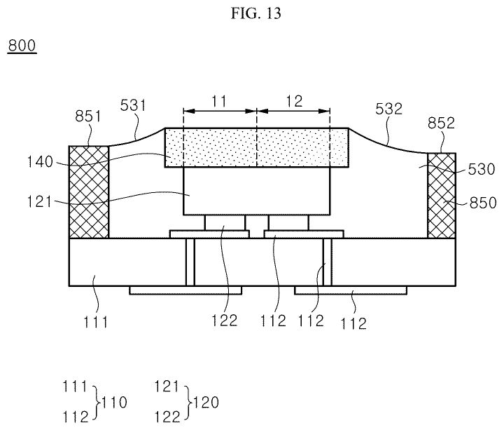

FIG. 13 is a sectional view of a light emitting apparatus according to an eighth embodiment of the present invention.

Referring to FIG. 13, a light emitting apparatus 800 according to an eighth embodiment may include a substrate 110, a light emitting layer 120, a wavelength conversion layer 140, a barrier layer 530, and a blocking layer 850.

In the light emitting apparatus 800 according to this embodiment, the barrier layer 530 may have a structure including an inclined and curved surface. In this embodiment, the barrier layer 530 may have different structures on both sides of an upper surface thereof relative to the wavelength conversion layer 140.

For example, the upper surface of the barrier layer 530 adjacent the first light exit region 11 may be referred to as a first upper surface 831 and the upper surface of the barrier layer 530 adjacent the second light exit region 12 may be referred to as a second upper surface 832.

Each of the first upper surface 831 and the second upper surface 832 of the barrier layer 530 has a height gradually decreasing from an end, which corresponds to an inner side edge thereof adjoining the wavelength conversion layer 140, to the other end, which corresponds to an outer side edge thereof. Here, the height of each of the other end of the first upper surface 831 and the other end of the second upper surface 832 of the barrier layer 530 may be greater than the height of the upper surface of the light emitting layer 120. Further, the height of the other end of the second upper surface 832 of the barrier layer 530 may be lower than the height of the other end of the first upper surface 831. Thus, in the barrier layer 530, the second upper surface 832 adjacent the second light exit region 12 having relatively low luminance may have a larger area than the first upper surface 831 adjacent the first light exit region 11 having relatively high luminance.

With such a structure, the barrier layer 530 can reflect more light over a larger area on the second upper surface 832 than on the first upper surface 831. Accordingly, the light emitting apparatus 800 according to this embodiment can increase the quantity of light directed toward a relatively low-luminance region by the barrier layer 530, thereby reducing the difference between a low-luminance region and a high-luminance region, thereby resolving luminance imbalance.

Depending on a difference in height between the first upper surface 831 and the second upper surface 832 of the barrier layer 530, the blocking layer 850 may also have different heights at both sides relative to the light emitting layer 120 and the wavelength conversion layer 140. For example, as in the barrier layer 530, a first upper surface 851 of the blocking layer 850 adjacent the first light exit region 11 may be placed higher than a second upper surface 852 of the blocking layer 850 adjacent the second light exit region 12. However, it should be understood that the structure of the blocking layer 850 is not necessarily changed based on the structure of the barrier layer 530.

In this embodiment, the blocking layer 850 has a structure in which the upper surface is lower than the upper surface of the wavelength conversion layer 140 and higher than the light emitting layer 120. However, it should be understood that the structure of the blocking layer 850 according to this embodiment is not limited thereto.

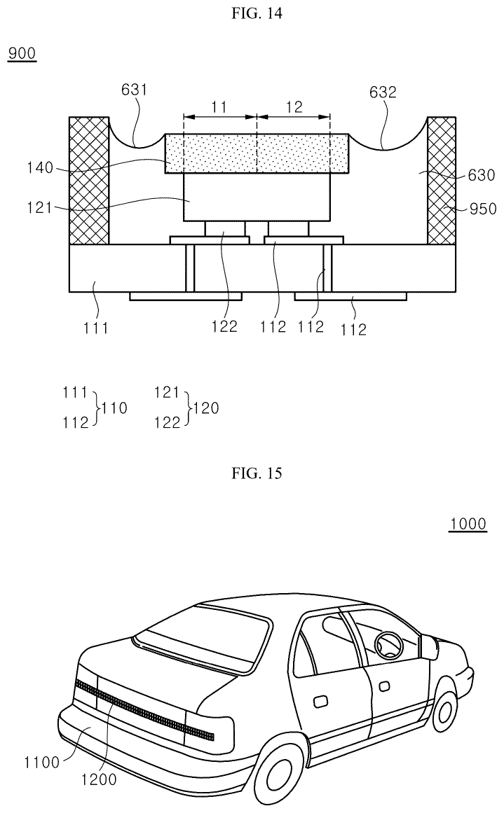

FIG. 14 is a sectional view of a light emitting apparatus according to a ninth embodiment of the present invention.

Referring to FIG. 13, a light emitting apparatus 900 according to a ninth embodiment may include a substrate 110, a light emitting layer 120, a wavelength conversion layer 140, a barrier layer 630, and a blocking layer 950.

In the light emitting apparatus 900 according to this embodiment, the barrier layer 630 may have a curved structure in which an upper surface is concave in a downward direction. With such a structure, the upper surface of the barrier layer 630 may have a larger area than an upper surface inclined in one direction. That is, the upper surface of the barrier layer 630 can reflect more light directed in the downward direction or toward the upper surface of the barrier layer 630.

Further, according to this embodiment, the lowest height of the second upper surface 932 of the barrier layer 630 may be higher than the lowest height of the first upper surface 931 thereof. Thus, the second upper surface 932 may have a larger radius of curvature than the first upper surface 931. That is, since the second upper surface 932 of the barrier layer 630 has a larger area than the first upper surface 931 thereof, the second upper surface 932 can have higher light reflectivity than the first upper surface 931. The radius of curvature of the first upper surface 931 may be adjusted to be greater than the radius of curvature of the second upper surface 932 by increasing the thickness of the barrier layer 630 under the first upper surface 931. Alternatively, the blocking layer 950 placed outside the second upper surface 932 may be formed to have a lower height than the blocking layer 950 placed outside the first upper surface 931 such that the second upper surface 932 has a greater radius of curvature than the first upper surface 931.

Since the barrier layer 630 according to this embodiment has a concave upper surface, light reflected from a region of the barrier layer 630 adjacent the outer side of the upper surface thereof can be effectively focused on a center of the light exit surface of the light emitting apparatus 900.

Furthermore, according to this embodiment, the blocking layer 950 may have an upper surface placed higher than the light exit surface of the light emitting apparatus 900. That is, the upper surface of the blocking layer 950 may be placed higher than the upper surface of the wavelength conversion layer 140. With this structure, the blocking layer 950 can prevent light from traveling in a downward or lateral direction of the light emitting apparatus 900 after being emitted from the light exit surface of the light emitting apparatus 900. Thus, the light emitting apparatus 900 according to this embodiment ensures that light can be emitted in the upward direction of the light exit surface of the light emitting apparatus 900, instead of spreading, in an inner range of the blocking layer 950 by the blocking layer 950. That is, the blocking layer 950 can absorb light outside a predetermined angular range such that the light emitting apparatus 900 has a beam angle in a predetermined angular range. For example, the light emitting apparatus 900 may have a beam angle of 80 degrees or more.

Referring to FIG. 14, since the upper surface of the blocking layer 950 is placed higher than the light exit surface of the light emitting apparatus 900, the other end of the upper surface of the barrier layer 630 may also be placed higher than the upper surface of the wavelength conversion layer 140. However, it should be understood that this embodiment is not limited thereto. Alternatively, the other end of the upper surface of the barrier layer 630 may be flush with or placed under the upper surface of the blocking layer 950.

The light emitting apparatuses 700, 800, 900 according to the seventh to ninth embodiments of the present invention shown in FIG. 12 to FIG. 14 can improve luminance uniformity through the barrier layers and the blocking layers each having different thicknesses on both sides thereof relative to the light emitting layers according to the previous embodiments, can increase the quantity of light using the barrier layers each having an inclined and curved upper surface, and can realize a narrow beam angle by focusing light within a predetermined light exit region. The light emitting apparatuses 100 to 900 according to the first to ninth embodiments of the present invention may be applied to lighting devices and displays to increase luminance thereof. In addition, the light emitting apparatuses 700 to 900 according to the seventh to ninth embodiments of the present invention can reduce light interference between adjacent light emitting apparatuses through the blocking layers thereof.

Accordingly, the light emitting apparatuses according to the embodiments may be applied to devices that require high luminance and low light interference in a certain area, such as headlamps of an automobile.

FIG. 15 is an exemplary view of a vehicle including a light emitting apparatus according to an embodiment of the present invention.

Referring to FIG. 15, a vehicle 1000 includes a main body 1100 and a lamp 1200 mounted on the main body. The lamp 1200 requires control of a light emitting region for directional guidance or adjustment of a projection region. Accordingly, at least a light emitting apparatus among the light emitting apparatuses 100 to 900 according to the embodiments described above with reference to FIG. 1 to FIG. 14 may be used as a light source for the lamp 1200.

According to this embodiment, the lamp 1200 may include a plurality of light emitting apparatuses 100 arranged. In addition, the lamp 1200 may control the plurality of light emitting apparatuses to individually operate each of the plurality of light emitting apparatuses. Thus, the lamp 1200 can easily adjust the emitting region or the projection region by independently controlling the plurality of light emitting apparatuses each having low light interference.

In the above embodiments, each of the light emitting apparatuses includes the wavelength conversion layer. However, it should be understood that the present invention is not limited thereto. That is, the light emitting apparatus may include a base free from a wavelength conversion material, instead of the wavelength conversion layer. In addition, when a plurality of light emitting apparatuses is provided as in the lamp, at least a light emitting apparatus of the light emitting apparatuses may include a base free from a wavelength conversion material, instead of the wavelength conversion layer. That is, according to this embodiment, a lamp including a plurality of light emitting apparatuses may include a structure in which the plurality of light emitting layers is arranged and a structure in which the wavelength conversion layer covers one or more of the plurality of light emitting layers.

Although some embodiments have been described herein with reference to the accompanying drawings, it should be understood that the foregoing embodiments are provided for illustration only and are not to be in any way construed as limiting the scope of the present invention. The scope of the present invention should be defined by the appended claims and equivalents thereto.

What is claimed is:

1. A light emitting apparatus comprising:
a substrate;
a light emitting layer disposed on the substrate and including a light exit surface configured to emit light;
a wavelength conversion layer disposed on the light emitting layer; and
a barrier layer disposed on the substrate, and covering at least a side surface of the light emitting layer and at least a side surface of the wavelength conversion layer, and configured to reflect the light emitted from the light emitting layer,
wherein the light exit surface of the light emitting layer includes a first light exit region and a second light exit region having a lower luminance than a luminance of the first light exit region,
wherein the barrier layer includes a first region adjacent to the first light exit region and a second region adjacent to the second light exit region the second region having a greater thickness than the first region, and
wherein a thickness of the barrier layer corresponds to a distance from an inner side surface of the barrier layer to an outer side surface thereof.

2. The light emitting apparatus according to claim 1, wherein an upper surface of the barrier layer is substantially flat.

3. The light emitting apparatus according to claim 1, wherein
an upper surface of the barrier layer includes a first upper surface adjacent to the first light exit region and a second upper surface adjacent to the second light exit region,
each of the first upper surface and the second upper surface includes a first end coupled with the wavelength conversion layer and a second end disposed on an opposite the first end, and
the first end and the second end of each of the first upper surface and the second upper surface is placed higher than an upper surface of the light emitting layer.

4. The light emitting apparatus according to claim 3, wherein the upper surface of the barrier layer has a height gradually decreasing from an inner side edge of the barrier layer to an outer side edge thereof.

5. The light emitting apparatus according to claim 4, wherein the second end of the first upper surface is disposed higher than the second end of the second upper surface.

6. The light emitting apparatus according to claim 4, wherein the upper surface of the barrier layer includes a curved surface.

7. The light emitting apparatus according to claim 3, wherein the upper surface of the barrier layer includes a curved surface concave in a downward direction.

8. The light emitting apparatus according to claim 7, wherein the second upper surface has a greater radius of curvature than a radius of curvature of the first upper surface.

9. The light emitting apparatus according to claim 1, wherein the wavelength conversion layer covers an upper surface of the light emitting layer and has a larger cross-sectional area than a cross-sectional area of the light emitting layer.

10. The light emitting apparatus according to claim 9, wherein the wavelength conversion layer has a larger cross-sectional area in a region thereof covering the second light exit region of the light emitting layer and an outer side surface of the second light exit region than in a region thereof covering the first light exit region of the light emitting layer and an outer side surface of the first light exit region.

11. The light emitting apparatus according to claim 10, wherein
a width from the outer side surface of the second light exit region to a second end of the wavelength conversion layer adjacent to the second light exit region is greater than a width from the outer side surface of the first light exit region to a first end of the wavelength conversion layer adjacent to the first light exit region.

12. A light emitting apparatus comprising:
a substrate;
a light emitting layer disposed on the substrate and includes a light exit surface configured to emit light;
a wavelength conversion layer disposed on the light emitting layer;
a barrier layer disposed on the substrate configured to cover side surfaces of the light emitting layer and the wavelength conversion layer, the barrier layer reflecting the light emitted from the light emitting layer; and
a blocking layer covering at least a surface of the barrier layer,
wherein the light exit surface of the light emitting layer comprises a first light exit region and a second light exit region having lower luminance than a luminance of the first light exit region, and
wherein the blocking layer has a greater thickness in a region thereof adjacent to the first light exit region than a thickness in a region thereof adjacent to the second light exit region.

13. The light emitting apparatus according to claim 12, further comprising:
a blocking layer surrounding a side surface of the barrier layer and configured to absorb the light emitted from the light emitting layer.

14. The light emitting apparatus according to claim 13, wherein the blocking layer has a lower light transmittance than a light transmittance of the barrier layer.

15. The light emitting apparatus according to claim 14, wherein an upper surface of the blocking layer is placed lower than an upper surface of the wavelength conversion layer and higher than an upper surface of the light emitting layer.

16. The light emitting apparatus according to claim 14, wherein an upper surface of the blocking layer is placed higher than an upper surface of the wavelength conversion layer.

17. A vehicle comprising:
a main body;
a lamp mounted on a surface of the main body; and
a plurality of light emitting apparatuses arranged on the lamp, at least one light emitting apparatus of the plurality of light emitting apparatuses comprising:
at least one light emitting layer;
a wavelength conversion layer covering an upper surface of the at least one light emitting layer; and
a barrier layer covering a side surface of the at least one light emitting layer and configured to reflect light emitted from the light emitting layer,
wherein a light exit surface of the light emitting layer comprises a first light exit region and a second light exit region having lower luminance than a luminance of the first light exit region,
wherein the barrier layer has a greater thickness in a region thereof surrounding the second light exit region than a thickness in a region thereof surrounding the first light exit region, and
wherein the thickness of the barrier layer corresponds to a distance from an inner side surface of the barrier layer to an outer side surface thereof.

18. The vehicle according to claim 17, wherein
an upper surface of the barrier layer comprises a first upper surface adjacent to the first light exit region and a second upper surface adjacent the second light exit region,
each of the first upper surface and the second upper surface comprises a first end coupled with the wavelength conversion layer and a second end placed opposite the first end, and
the first end and the second end of each of the first upper surface and the second upper surface are placed higher than the upper surface of the light emitting layer.

19. The vehicle according to claim 17, wherein an upper surface of the barrier layer comprises a curved surface.

20. The vehicle according to claim 17, wherein the light emitting apparatus further comprises a blocking layer surrounding a side surface of the barrier layer and configured to absorb the light emitted from the light emitting layer.
